(19) United States
(12) Patent Application Publication
(10) Pub. No.: US 2012/0125842 A1
(43) Pub. Date: May 24, 2012

(54) Microfluidic System And Corresponding Method For Transferring Elements Between Liquid Phases And Use Of Said System For Extracting Said Elements

(75) Inventors: Jean Berthier, Meylan (FR); Sophie Le Vot, Le Pont De Claix (FR); Florence Rivera, Meylan (FR)

(73) Assignee: Commissariat A L'Energie Atomique Et Aux Energies Alternatives, Paris (FR)

(21) Appl. No.: 13/378,875

(22) PCT Filed: Jun. 18, 2010
(86) PCT No.: PCT/FR2010/000453

§ 371 Date: Jan. 23, 2012

(30) Foreign Application Priority Data
Jun. 19, 2009 (FR) 09 02988

(51) Int. Cl. B01J 19/00; B01D 11/00; B81B 1/00; B01J 13/18

(52) U.S. Cl. 210/634; 422/255; 425/5; 264/4.7

(57) ABSTRACT

The invention relates to a microfluidic system including a unit for extracting elements from one liquid phase to at least one other liquid phase, a use of said system for performing said extraction, preferably for gelling polymer capsules coating such elements by cross-linking, and a method for extracting said elements. Said system comprises a substrate in which a network of micro-channels is etched, including a unit (10) for extracting elements (E), including: a depleting micro-channel (11) which carries a first phase (A) to be depleted; at least one enriching channel (12) which carries a second phase (B) to be enriched, said micro-channels meeting at two junctions upstream (Ja) and downstream (Jb) and forming a transfer chamber (13) between said junctions, each junction being such that the micro-channels are axially parallel or form an acute angle on either side of the junction; and a transfer means (14) arranged in the depleting micro-channel for diverting the elements towards the enriching micro-channel. According to the invention, the transfer means includes blocks (14) extending transversely to the axis of the depleting micro-channel, and the extraction unit includes an interface stabilising means (16) arranged downstream from the transfer means between the junctions and including pillars (16) or a surface coating located on an area of the downstream junction facing at least one of the micro-channels.

The present invention relates to a microfluidic system comprising a unit for extracting elements of micrometric or millimetric size from one liquid phase to at least one other liquid phase, a use of said microfluidic system for performing said extraction preferably for gelling polymer capsules coating said elements by crosslinking, and a corresponding method for extracting said elements. The invention applies to biological or nonbiological elements of small size, such as DNA strands, proteins, cells, clusters of cells or even auxiliary objects in biotechnological applications, such as magnetic beads or fluorescent particles, as nonlimiting examples.

The transfer of elements of small size from one liquid phase to another immiscible liquid phase is a problem of considerable importance. We may for example cite document EP-B1-787 029 for such transfer, performed exclusively by diffusion. As for transfer by forced convection, in general it is difficult as it is necessary to constrain the elements by a force which normally directs them to flow and, especially in the case of a two-phase system, this force must be sufficient for said elements to cross the interface between the two liquids. Now, passage is impeded by the surface tension between the two liquids and by capillary forces. For effecting this transfer passively, it is known to use the deflector principle, which can take several forms, for example a network of pillars or a simple oriented line of pillars.

The technique of networks of pillars was developed for sorting by “Deterministic Lateral Displacement” (DLD). This technique (see in particular the article by D. W. Inglis, J. A. Davis, R. H. Austin and J. C. Sturm, Critical particle size for fractionation by deterministic lateral displacement, Lab Chip 6: 655-658, 2006) is based on the use of a periodic network of obstacles which may or may not perturb the trajectory of the particles to be sorted. The particles smaller than a critical size Dc (fixed by the geometry of the device) are not diverted overall by the pillars, whereas those larger than Dc are diverted in the same direction at each row of blocks, which permits separation of the particles by size. However, it appears that this “DLD” technique to the best of our knowledge has so far only been used for sorting of particles in a single phase without change of carrier fluid, as illustrated for example in documents WO-A-2004/037374, US-A-2007059781 or US-A-2007026381.

The gelling of polymer droplets is a typical example of the need for a change of carrier fluid. In biotechnology, the use of such droplets containing biological objects is more and more promising. Nevertheless, the gelling step, which must follow the step of production of the droplets, is a technological obstacle at present. In fact, these droplets or capsules, which are typically based on a hydrogel (e.g. an alginate hydrogel), are produced in an organic phase (e.g. soybean oil) and must be transferred to an aqueous phase containing polyions such as calcium ions as crosslinking agent, to obtain gelling of the hydrogel. The existing techniques are all deficient, as they cause considerable deformation of the capsules, which must be preserved as far as possible in their initial spherical shape. Therefore transfer must not be effected “brutally”, exerting forces of great intensity on the capsules, and this is all the more noticeable when the elements to be encapsulated are of large size (between 5 μm and 1 mm) and are fragile, such as cells or clusters of cells, for example.

The aim of encapsulating cells, such as islets of Langerhans for example, in microcapsules is to protect them against attack by the immune system during transplantation. The porosity of the capsule must be such that it permits entry of molecules of low molecular weight that are essential to the metabolism of the encapsulated cells (nutrients, oxygen, etc.) while preventing entry of substances of higher molecular weight such as antibodies or cells of the immune system. This selective permeability of the capsule ensures absence of direct contact between the encapsulated cells of the donor and the cells of the immune system of the transplant recipient, which makes it possible to limit the doses of immunosuppressant treatment used during transplantation (treatment of severe side effects). Besides their selective permeability, the capsules produced must be biocompatible, mechanically strong, and of suitable size for the cells that are to be encapsulated.

After formation of the capsules coating the cells, it is necessary to proceed to gelling of them, to solidify the protective layer.

Gelling of capsules of alginate containing cells is effected conventionally by a method of external gelling, where the alginate beads are crosslinked in a bath of polycations (generally of CaCl₂) by diffusion of the polycations into the alginate capsule at a pH close to 7 to maximize the viability of the cells. This technique has the drawback that it does not allow capsules to be obtained that are highly homogeneous (high polydispersity) and spherical. Reference may notably be made to the article of K. Liu, H. J. Ding, Y. Chen, X. Z. Zhao, Droplet-based synthetic method using microflow focusing and droplet fusion, Microfluid. Nanofluid, Vol. 3, pp. 239-243, 2007, which presents a microfluidic system employing contact in a circular “deceleration” chamber and consisting of coalescing each alginate capsule with an aqueous droplet containing calcium carbonate as crosslinking agent, with gelled capsules that differ markedly from the required spherical geometry.

There is also a method of internal gelling, which consists of gelling the alginate capsules by putting them in contact with crystals of calcium carbonate in the alginate phase. When the droplets of alginate are immersed in a solution containing acetic acid, the calcium ions are released and bind to the alginate, thus permitting gelling. This method, although making it possible to obtain capsules that are more homogeneous and roughly spherical, nevertheless has the drawback of having to be employed at an acid pH close to 6.4, with adverse effects on the viability of the cells. Reference may be made to the article by V. L. Workman, S. B. Dunnett, P. Kille, and D. D. Palmer, On-chip alginate microencapsulation of functional cells, Macromolecular rapid communications, Vol. 29 (2), pp. 165-170, 2008 for a description of a microfluidic system employing this method of internal gelling.

The known techniques of encapsulation/gelling also have the following drawbacks:
the size of the capsules is not suitable for the size of the cells or islets to be encapsulated,
encapsulation, which is most often followed by external gelling, by which the capsules are gelled by immersion in a bath of polycations, is not automated but manual, which leads to a variation of crosslinking time from one capsule to another, and
the dispersion in size of the gelled capsules increases as the size of the droplets decreases.

One aim of the present invention is to propose a microfluidic system notably making it possible to overcome the aforementioned drawbacks with respect to the gelling of capsules, said system having a substrate in which a network of microchannels is etched, comprising a unit for extracting elements of micrometric or millimetric size and which is covered with a protective cover, said extraction unit comprising:
a depleting microchannel in which a first phase to be depleted circulates,
at least one enriching microchannel in which a second phase to be enriched circulates, said depleting and enriching microchannels meeting in pairs at two upstream and downstream junctions forming a transfer chamber between said junctions, each junction being such that the central axes of these microchannels are parallel or form an acute angle on either side of the junction, and
transfer means arranged in said depleting microchannel and configured for transferring said elements from this depleting microchannel to said at least one enriching microchannel.

For this purpose, a microfluidic system according to the invention is such that said transfer means comprise blocks extending transversely to the central axis of said depleting microchannel, and such that the extraction unit further comprises interface stabilizing means which are arranged downstream of the transfer means between said junctions and which comprise pillars or else a surface coating located on an area of the downstream junction facing at least one of the microchannels.

“Size” of the elements to be extracted, such as capsules coating clusters of cells, for example, means, in the present description, the diameter or more generally the largest transverse dimension of each of these elements.

Millimetric size means a size of the elements between some 100 μm and a few mm. Micrometric size means a size of the elements of less than 100 μm.

Axis of each microchannel means a central axis parallel to the direction of flow of the liquid in the microchannel.

According to another characteristic of the invention, said interface stabilizing means can be situated near said blocks and are approximately aligned with said downstream junction, and said interface stabilizing means can moreover perform a nonreturn function of the elements that have been separated from said first phase by said blocks or else are associated with separate means performing this nonreturn function.

Advantageously, these interface stabilizing means can comprise said pillars which preferably have projecting edges and the last of which can be adjacent to said downstream junction, and said pillars can be regularly spaced with the first pillar being adjacent to the last block of the transfer means. The fact that the edges of the pillars are projecting means there is good bond of the interface.

In the case when said pillars are used as interface stabilizing and nonreturn means, they are separated from one another in pairs by a distance that is envisaged to be less than the size of the elements transferred.

According to another characteristic of the invention, said transfer chamber extends continuously between said or each upstream junction and the corresponding downstream junction, which is preferably also designed so that the flows remain roughly parallel along this chamber.

Advantageously, said or each upstream junction and said corresponding downstream junction can each have, viewed from above:
approximately a V shape, said unit then preferably having the form of a Y-shaped junction, or else
approximately a U shape, said unit then preferably having a form of one or more Hs joined together, of which the or each broadened cross-bar forms said chamber and whose uprights form the inlets and outlets.

Thus, both the or each upstream junction and the or each downstream junction are preferably such that the streams or flows of the two phases that converge there and that diverge from there are respectively centered on axes that are roughly parallel or make an acute angle between them. It should be noted that this parallelism or this acute angle of the streams is not to be confused with the parallelism or the acute angle characterizing the corresponding junction itself (i.e. the external wall of said junction), but is evidence of the internal geometry of the junction in question, as will be explained in more detail below.

Also advantageously, the or each upstream junction and the or each downstream junction can be extended in the direction of the opposite junction by an impermeable separating partition between phases extending over a distance configured to increase the parallelism of said streams in said chamber. It should be noted that these upstream and downstream separating partitions prolonging the internal faces of respective walls of the upstream and downstream junctions make it possible to provide directions of adjacent streams meeting and separating that are roughly parallel, even if these junctions each form a right angle or even obtuse angle at the external face of their wall. In other words, these separating partitions can make it possible to correct a junction angle that is too high (notably greater than or equal to 90°) between two inlets or two outlets so that the streams that meet there or move apart are roughly parallel.

Advantageously in connection with the aforementioned variant for said interface stabilizing means, the latter can comprise said surface coating, which is located on at least one face of said separating partition.

According to another characteristic of the invention, this system is provided with external means for circulating the phases under pressure, to cause them to circulate by forced convection in said inlets and outlets, and said transfer means are of the hydrodynamic type with exclusively passive fluidics.

It should be noted that the extraction unit of the microfluidic system differs from those using purely diffusive transfer, for example in the aforementioned document EP-B1-787 029. Moreover, this unit does not employ active methods—for example electrical—which can damage the elements that are being manipulated, notably in the case of biological objects, but only a passive method (the only source of energy used being the micropumps external to the system).

The fluids circulating respectively in the depleting microchannel and in the enriching microchannel flow in the same direction. They are preferably immiscible, which means there is a well-delimited interface between these two fluids. “Well-delimited” means that it extends over a small thickness, less than a few nm.

According to a first embodiment of the invention, said transfer blocks, preferably having a wall without projecting edges such as cylindrical blocks, are arranged on at least one row forming for the or each row an angle from 5° to 85° with the direction of this microchannel and preferably between 20° and 60°, said blocks being configured for selectively diverting some or all of said elements to force them to move towards said or each adjacent enriching microchannel. It should be noted that the or each row of blocks thus extends transversely to the direction of flow of the fluid circulating in said depleting microchannel.

Advantageously, the transfer means according to this example can comprise several rows of blocks which are arranged successively along the depleting microchannel in the transfer chamber, and which comprise:
an upstream row adjacent to said upstream junction, which extends moreover on at least a portion of the passage cross-section of said adjacent depleting microchannel and whose obstacles are dimensioned and spaced so as to oppose the passage of at least one category of the elements of larger size, greater than the spacing between these upstream obstacles and divert them to a distal outlet of this enriching microchannel, which is thus coupled to this upstream row, and
at least one downstream row adjacent to said downstream junction, which extends over a passage cross-section less than that of the upstream row and whose obstacles are dimensioned and spaced so as to oppose the passage of at least one other category of the elements of smaller size than the preceding elements, greater than the spacing between these downstream obstacles which have crossed the upstream row and divert them to this enriching microchannel, channelling them to a proximal outlet of the latter which forms for example a Y-shaped junction with said distal outlet and with the depleting microchannel and which is thus coupled to this downstream row.

According to a variant of this first embodiment, these diverting transfer means can be arranged in the form of rows of blocks which are arranged in the chamber transversely to the depleting microchannel and, depending on the application, to the enriching microchannel, and which are designed for obtaining a deterministic lateral displacement (“DLD”) allowing the elements to pass, gradually diverting them to each passage from one row to the next row.

According to another variant of this first embodiment, these diverting transfer means can further comprise (i.e. in addition to said blocks) at least one deflector which consists of an internal projection of the lateral wall of said depleting microchannel formed opposite said transfer chamber and which has for example a triangular cross-section.

Concerning said interface stabilizing means that are configured to stabilize the interface between said streams in mutual contact, it should be noted that they make it possible to prevent drops of liquid of one phase (and notably of the phase to be depleted) being formed in another phase (notably in the phase to be enriched). Said stabilizing means are useful when the two phases circulating in adjacent microchannels are immiscible.

As noted above, said transfer chamber can also comprise nonreturn means for providing a so-called nonreturn function, i.e. they oppose said elements transferred to the enriching phase being returned to the depleted phase. This transfer chamber can comprise interface stabilizing and nonreturn means, i.e. providing interface stabilizing and nonreturn functions simultaneously.

These interface stabilizing means and these nonreturn means are arranged downstream of said transfer means in an interface zone between these streams situated approximately in the prolongation of the downstream junction. Interface stabilizing means can also be arranged upstream of this interface zone.

According to a second embodiment of the invention, said depleting and enriching microchannels have their upstream and downstream junctions in the form of Y-shaped junctions, said transfer blocks, for example of square section, being situated downstream of the upstream junction and adjacent to the downstream junction, said blocks being regularly spaced in the prolongation of the lateral wall of the inlet of the depleting microchannel which is opposite the inlet of the enriching microchannel, and in the prolongation of the outlet of the enriching microchannel, said outlet being roughly coaxial with the inlet of the depleting microchannel, so as to channel the elements without diverting them from their path from the inlet of the depleting microchannel to the outlet of the enriching microchannel.

Advantageously, these transfer means that do not employ diversion of the elements to be extracted can consist exclusively of such a row of blocks that extends transversely to the direction of flow of the fluid circulating in the depleting channel. The spacing between these blocks is then less than the size of the elements to be separated. In a first part, such a row of blocks constitutes a means for transferring the elements from the depleting microchannel to the enriching microchannel and, in a second part, this row of blocks is in contact with the interface between the fluids circulating respectively in the depleting and enriching microchannels. In this second part, the row of blocks then constitutes a means for interface stabilization and nonreturn of the separated elements.

According to another characteristic of the invention common to the two aforementioned embodiments, said extraction unit can be coupled downstream to at least one means for reducing the head losses, such as a coil, which is also included in said network of microchannels and which is configured to keep the pressure of the second enriching phase slightly above that of the first depleting phase to prevent droplets of the latter entering this second enriching phase and so as to have roughly equal flow rates on both sides of the interface. It should be noted that any means making it possible to reduce the head losses can be used, instead of said coil, which is only one example of implementation of the invention.

According to another characteristic of the invention also common to these two embodiments, said extraction unit can be coupled upstream to a unit for encapsulating the elements, such as clusters of cells, also included in said microfluidic system, the extraction unit then being configured to provide gelling by crosslinking of each polymer capsule obtained at the outlet of the encapsulation unit, a pre-gelling module being optionally interposed between these encapsulation and extraction units, and an additional encapsulation module for example of the microfluidic flow-focusing device (“MFFD”) type that can be provided downstream of the extraction unit.

In general, it should be noted that the microfluidic systems according to the invention should preferably be sterilizable, as the gelled capsules obtained must be able to be transplanted into an individual, if required. A system according to the invention can be made of a plastic (for example PDMS), glass or silicon, as nonlimiting examples.

A microfluidic system according to the invention, as defined by the set of aforementioned characteristics, can be used advantageously for extracting elements of millimetric or micrometric size, such as clusters of cells, for example islets of Langerhans, from a first liquid phase to be depleted to at least one second liquid phase to be enriched, which may or may not be miscible with said first phase or with an adjacent intermediate phase.

According to a preferred embodiment of the invention, said use consists of performing gelling by crosslinking of polymer coating capsules which are previously formed around these elements within said microfluidic system and which are for example based on an alginate hydrogel, by transferring these capsules respectively coating said elements from an oily organic phase to be depleted containing them to an aqueous phase to be enriched, which is immiscible with said oily phase and which contains a gelling agent preferably based on polyions, such as calcium ions.

It should be noted that these preformed capsules can be monolayer or multilayer and are advantageously biocompatible, mechanically strong and have selective permeability. The polymer used for encapsulation can be for example an alginate hydrogel, the polymer most commonly used for encapsulation. However, other encapsulation materials could be selected, such as chitosan, carrageenans, agarose gels, polyethylene glycols (PEG), as nonlimiting examples, provided that the encapsulation unit is adapted to the type of gelling that the polymer selected requires.

According to another embodiment of the invention, said use consists of using first and second phases to be depleted and to be enriched that are mutually miscible in pairs and of generating a transverse concentration gradient there, downstream of said transfer chamber.

A method of extraction according to the invention of elements of millimetric or micrometric size, such as clusters of cells, for example islets of Langerhans, from a first liquid phase to be depleted to at least one second liquid phase to be enriched, which is or is not miscible with said first phase or with an adjacent intermediate phase, comprises contacting the respective streams of said phases, which are compelled to flow by forced convection in laminar conditions (preferably “hyperlaminar”, i.e. with a Reynolds number of less than 1) in a depleting microchannel and at least one enriching microchannel etched in a substrate of a microfluidic system, in such a way that said streams are, on the one hand, roughly parallel to one another or form an acute angle by meeting at two upstream and downstream junctions between said microchannels and, on the other hand, remain parallel throughout the duration of their mutual contact, to force the transfer of said elements from one phase to the other exclusively by passive fluidics.

According to the invention, this method is such that it comprises a transfer of said elements from the depleting microchannel to said at least one enriching microchannel by means of blocks extending transversely to the central axis of said depleting microchannel, and then an interface stabilization performed downstream of said blocks and upstream of said downstream junction.

Advantageously, this interface stabilization can be effected by an arrangement of pillars which are situated near said blocks and which are approximately aligned with said downstream junction, or by a surface treatment located on an area of said downstream junction facing at least one of said microchannels, said surface treatment being for example of the lipophilic or hydrophobic type.

According to another characteristic of the invention, this method can further comprise the performance of a nonreturn function of the elements that have been separated from said first phase by said blocks, this nonreturn function resulting from said stabilization or else being performed separately from the latter.

As is known, the size of the islets of Langerhans can vary from 20 to 400 μm, compared with 1 to 10 μm on average for one cell, and these islets must be manipulated even more cautiously than single cells owing to their fragility and their low cohesion, and this is provided by the microfluidic systems of the invention.

Other advantages, characteristics and details of the invention will become clear from the rest of the description given below, referring to the appended drawings, given solely as examples, and in which:

FIG. 1 is a schematic cross-sectional view of a microfluidic system according to the invention in a first step of its manufacturing process showing oxidation of the substrate,

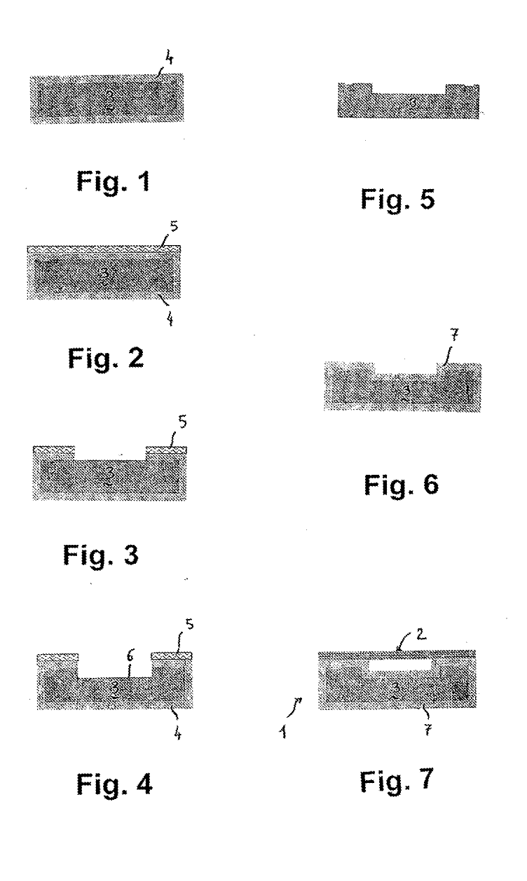

FIG. 2 is a schematic cross-sectional view of the system in FIG. 1 in a second step of its manufacturing process showing spreading of a photosensitive resin on said oxidized substrate,

FIG. 3 is a schematic cross-sectional view of the system in FIG. 2 in a third step of its manufacturing process showing the result of the next steps of photolithography and of dry etching, for creating the microchannels,

FIG. 4 is a schematic cross-sectional view of the system in FIG. 3 in a fourth step of its manufacturing process showing the result of steps of deep etching,

FIG. 5 is a schematic cross-sectional view of the system in FIG. 4 in a fifth step of its manufacturing process showing the result of a step of stripping of the resin and of deoxidation by wet etching,

FIG. 6 is a schematic cross-sectional view of the system in FIG. 5 in a sixth step of its manufacturing process showing the result of a step of oxidation,

FIG. 7 is a schematic cross-sectional view of the system in FIG. 6 in a seventh step of its manufacturing process showing the result of a step of sealing of a protective cover in order to delimit the cross-section of the microchannels,

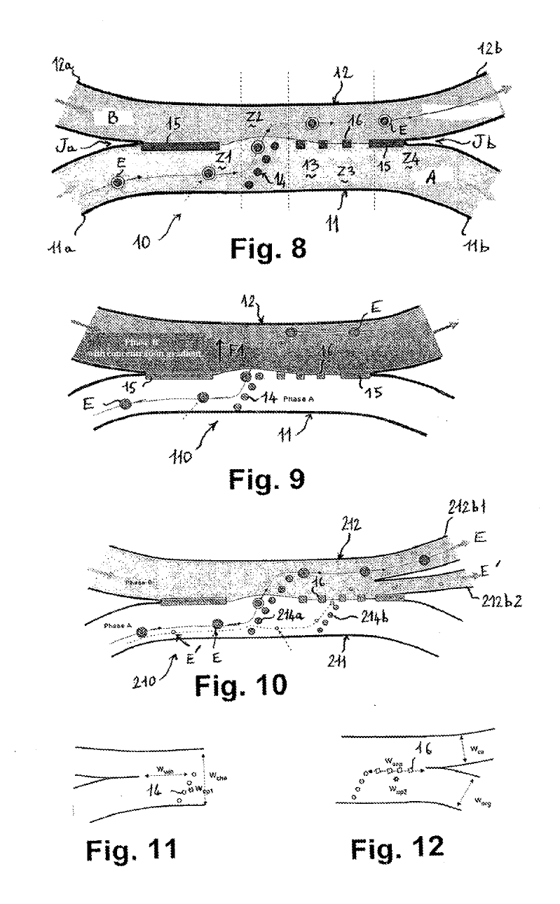

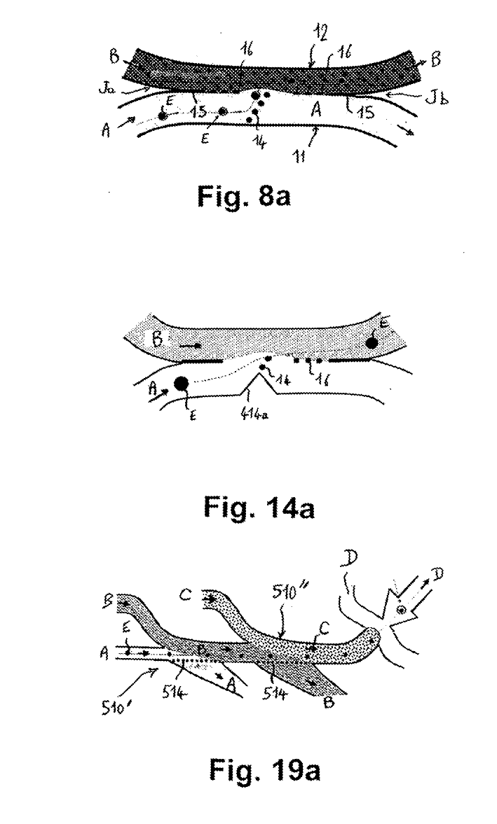

FIG. 8 is a schematic partial top view of a two-phase extraction unit of a microfluidic system according to an example of the first embodiment of the invention, showing the diverting of the encapsulated elements for transferring them from a phase to be depleted to a phase to be enriched,

FIG. 8a is a schematic partial top view of a two-phase extraction unit of a microfluidic system according to another example of the first embodiment of the invention, as a variant of FIG. 8,

FIG. 8b is a schematic partial top view of another variant of the two-phase extraction unit of FIG. 8,

FIG. 9 is a schematic partial top view of a two-phase extraction unit according to a variant of FIG. 8 according to the first embodiment and also showing the diverting of these elements,

FIG. 10 is a schematic partial top view of a two-phase extraction unit according to another variant of FIG. 8 according to the first embodiment, showing the respective diverting of two size categories of these elements,

FIG. 11 is a schematic partial top view showing a dimensional example of an upstream junction with two inlets of an extraction unit according to FIGS. 8 to 10,

FIG. 12 is a schematic partial top view showing a dimensional example of a downstream junction with two inlets of an extraction unit according to FIGS. 8 to 10,

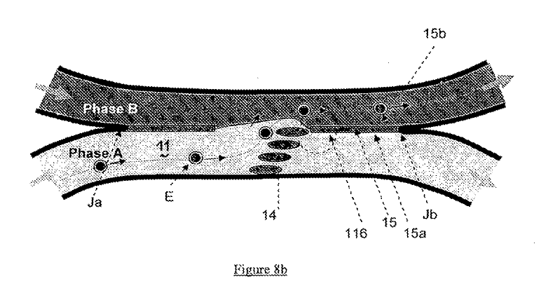

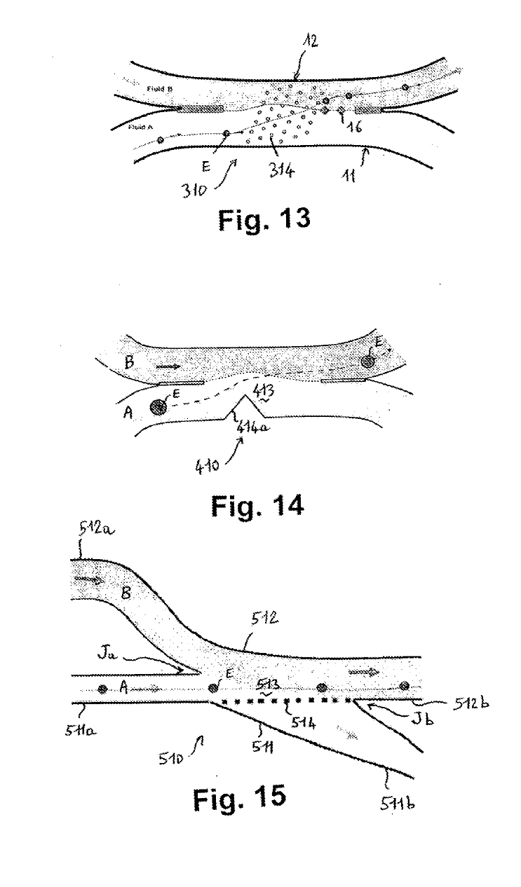

FIG. 13 is a schematic partial top view of a two-phase extraction unit according to another variant of FIG. 8 according to the first embodiment, showing gradual diverting of these elements,

FIG. 14 is a schematic partial top view of a two-phase extraction unit according to another variant of FIG. 8 according to the first embodiment, showing diverting of these elements by a deflector,

FIG. 14a is a schematic partial top view of a two-phase extraction unit according to a variant of FIG. 14 where the deflector is coupled to the diverting means of FIGS. 8 to 12,

FIG. 15 is a schematic partial top view of a two-phase extraction unit according to an example of the second embodiment of the invention, showing channelling, without diverting, of these elements for transferring them from a phase to be depleted to a phase to be enriched with these elements,

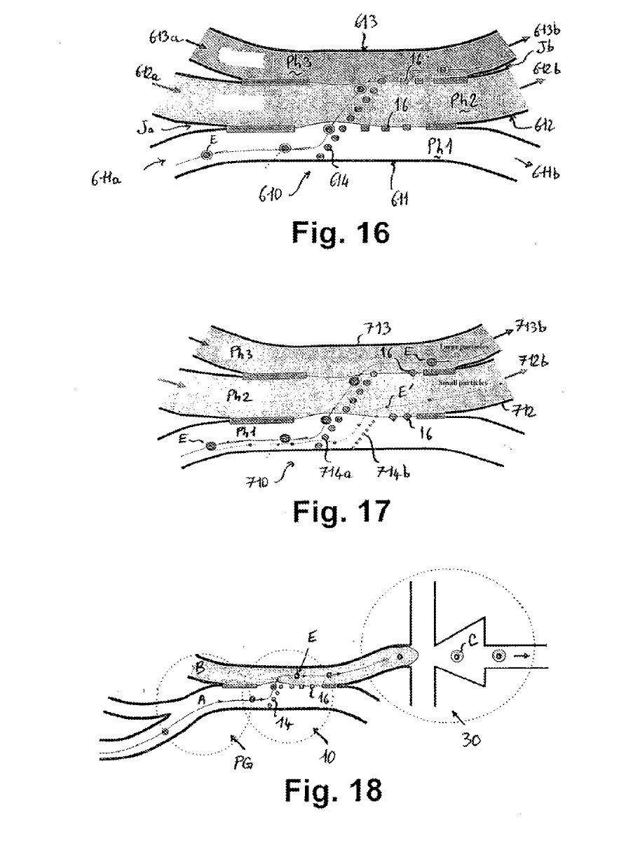

FIG. 16 is a schematic partial top view of a three-phase extraction unit according to an example of the first embodiment of the invention, showing the diverting of the elements for their successive transfer to two phases, respectively intermediate then to be enriched with these elements,

FIG. 17 is a schematic partial top view of a three-phase extraction unit according to a variant of FIG. 16 according to the first embodiment, showing the respective diverting of two size categories of these elements to the other two phases,

FIG. 18 is a schematic partial top view of a microfluidic system according to the invention whose extraction unit is according to FIG. 8 and is coupled upstream to a capsule pre-gelling module and downstream to an additional encapsulation module for obtaining double encapsulation of the extracted elements,

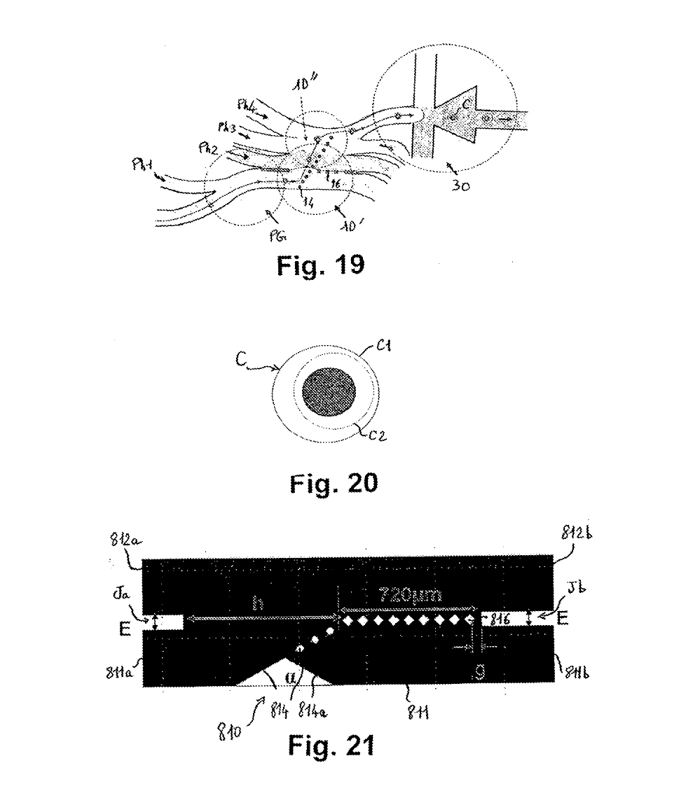

FIG. 19 is a schematic partial top view of a microfluidic system according to a variant of FIG. 18 which only differs from the latter in that the extraction unit coupled to these modules uses four phases for finally obtaining a three-layer capsule,

FIG. 19a is a schematic partial top view of a microfluidic system according to a variant of FIG. 19 employing extraction units in series according to the principle of FIG. 15,

FIG. 20 is a schematic cross-sectional view of a gelled capsule obtained by a system according to FIG. 18 or 19, showing the centering of each element obtained in this capsule,

FIG. 21 is a micrograph showing partially, in top view, a two-phase extraction unit with deflector according to the first embodiment of the invention according to a variant of FIGS. 8 and 14 combined, the diverted elements not being visible,

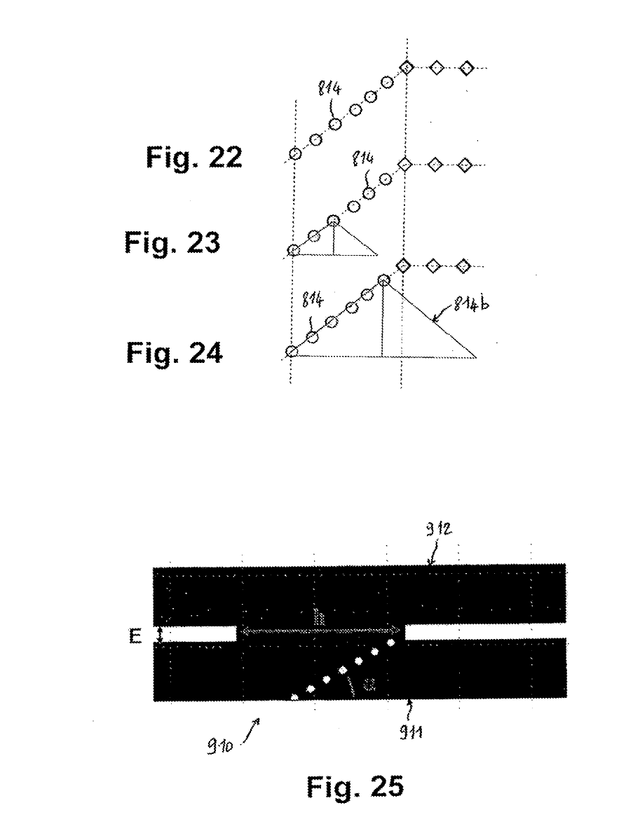

FIG. 22 is a schematic top view of an example of transfer means and stabilizing and nonreturn means usable in an extraction unit of the type as in FIG. 8,

FIG. 23 is a schematic top view of another example of transfer and stabilizing/non-return means usable in an extraction unit with deflector of the type as in FIG. 21,

FIG. 24 is a schematic top view of another example of transfer and stabilizing/non-return means usable in an extraction unit of the type as in FIG. 21 but with a larger deflector,

FIG. 25 is a micrograph showing partially, in top view, a two-phase extraction unit according to the first embodiment of the invention according to a variant of FIG. 21 but without deflector, the diverted elements not being visible,

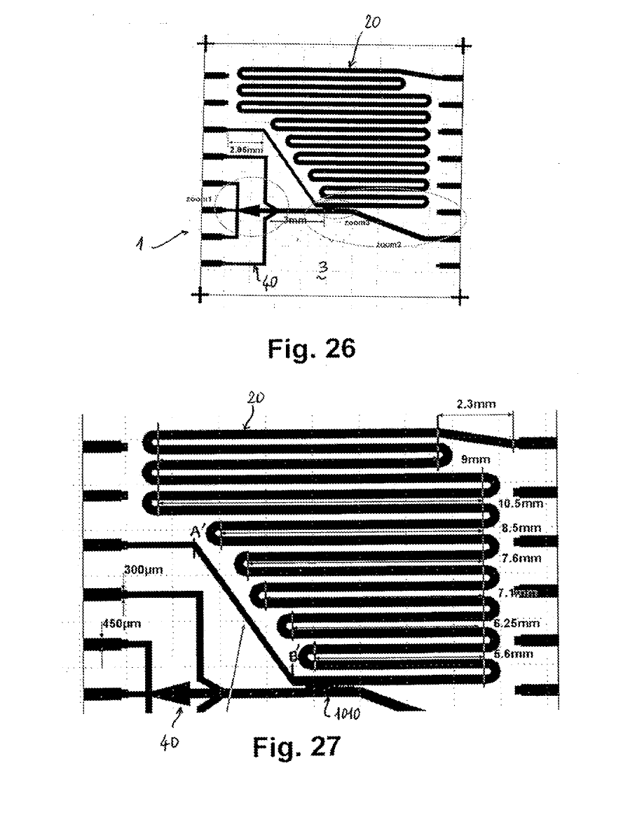

FIG. 26 is a micrograph showing a general top view of a microfluidic system according to the invention whose extraction unit for capsule gelling is coupled upstream to a unit for encapsulating the elements to be extracted, and downstream to a coil for regulating the respective pressures and flow rates of the two phases to be depleted and to be enriched,

FIG. 27 is a micrograph showing locally in top view, and on a larger scale, the coil in FIG. 26 coupled to the extraction unit,

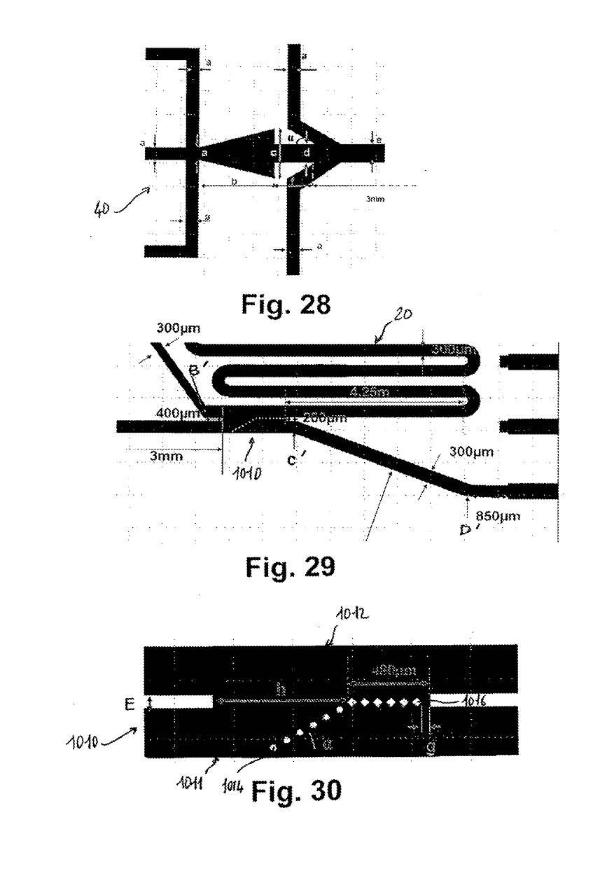

FIG. 28 is a micrograph showing locally in top view, and on a larger scale, the encapsulation unit in FIG. 26,

FIG. 29 is a micrograph showing locally in top view, and on a larger scale, the extraction unit in FIG. 26 coupled to the coil, and

FIG. 30 is a micrograph showing locally in top view, and on an even larger scale, the extraction unit in FIG. 29, which is of the type as in FIG. 22.

A microfluidic system 1 according to the invention can for example be produced as follows, referring to FIGS. 1 to 7 which present various steps based on known methods of silicon microelectronics, i.e. notably lithography, deep etching, oxidation, “stripping” and sealing of a protective cover 2 on the substrate 3. This silicon technology has the advantage of being very precise (of the order of a micrometer) and does not have limitations as to the depths of etching or to the widths of the patterns. More precisely, the protocol for production of the microsystem 1 is as follows:

A deposit of silicon oxide 4 (FIG. 1) is made on the silicon substrate. Then a photosensitive resin 5 is deposited by spreading on the front face (FIG. 2), after which the silicon oxide 4 is etched through the layer of resin 5 by photolithography and dry etching of the silicon oxide 4, stopping on the silicon substrate 3 (FIG. 3).

This substrate 3 is then etched to the desired depth of the microchannels by deep etching 6 (FIG. 4), then the resin is “stripped” (FIG. 5). The thermal silicon oxide 4 that remains is then removed by deoxidation by wet etching (FIG. 5), then a new layer of thermal oxide 7 is deposited (FIG. 6).

The chips obtained are then cut out and a protective cover 2 of glass—or of some other transparent material to allow observation—is sealed, for example by anodic sealing or direct sealing (FIG. 7).

Before assembly of the microchannels or capillaries (not shown), a surface treatment of the hydrophobic silanization type can also be carried out.

The protocol described above is one of the many manufacturing protocols that can be followed. Moreover, for substrate 3 it is possible to use a material other than silicon, for example a PDMS (polydimethylsiloxane) or else another elastomer, by molding on a “master” (i.e. matrix) prepared beforehand, for example by photolithography.

The extraction unit 10 in FIG. 8 has two microchannels, respectively depleting 11 and enriching 12, which are juxtaposed roughly parallel on substrate 3 and in which two liquid phases are intended to circulate, solely by forced convection, one to be depleted A and the other to be enriched B in elements E to be extracted, which are preferably selected to be immiscible with one another (these phases A and B being respectively oily and aqueous in the preferred case of using unit 10 for gelling polymer capsules coating the elements E). Microchannel 11 has an inlet 11a and an outlet 11b, and microchannel 12 has an inlet 12a and an outlet 12b, which form respectively, with 11a and 11b, an upstream junction Ja and a downstream junction Jb both as Y-shaped junctions (i.e. forming a V with branches brought together at a very small acute angle and slightly splayed outwards). The microchannels 11 and 12 are joined together between these junctions Ja and Jb, forming a transfer chamber 13, which is designed for mutual contacting of phases A and B circulating in “hyperlaminar” conditions (Reynolds number less than 1) so as to transfer, by exclusively hydrodynamic means 14 located in said chamber 13, elements E such as encapsulated clusters of cells in this implementation, by diverting these elements from microchannel 11 to microchannel 12.

As a result of these Y-shaped junctions Ja and Jb, the streams of phases A and B converge in contact with one another downstream of Ja and diverge from one another upstream of Jb in directions that are roughly parallel each time, like the streams of these phases A and B in the transfer chamber 13 which are envisaged to remain parallel to one another during their circulation in contact with one another. The phases A and B preferably circulate in the same direction.

For further optimization of this parallelism of the streams in chamber 13, it is envisaged to add a separating partition 15 impermeable to phases A and B at the internal connecting point of each junction Ja, Jb, in such a way that said partition 15 is roughly centered on the bisector of this junction Ja, Jb on the inside of the latter (i.e. on the internal face of the wall thereof). In other words, these two partitions 15 are directed towards one another, being roughly aligned with one another and with the interface of contact between phases A and B in chamber 13.

As can be seen in FIG. 8a, partition 15 of the upstream junction Ja can be prolonged by a row of separating pillars 16 aligned on the axis of said partition 15. It should be noted that as a variant, this upstream partition 15 could be replaced with such pillars 16 aligned on the axis of the bisector of this upstream junction Ja.

As can be seen in FIG. 8, the extraction unit 10 can be divided essentially into:
a zone Z1 initiating the contact between phases A and B;
a zone Z2 which is situated in chamber 13 and in which there are the diverting transfer means 14 formed in this example from a row of regularly spaced blocks (preferably cylindrical so as not to alter the elements E), said blocks 14 extending across the passage cross-section of microchannel 11 and almost to the interface between phases A and B (i.e. to the zone where microchannels 11 and 12 meet) at an angle of about 45° to the direction of this microchannel 11, so as to oppose the passage of the elements E, diverting them to microchannel 12;
a zone Z3 comprising a row of pillars 16 parallel to the flow of phases A and B and preferably of polygonal section (for example square), said pillars 16 being designed to stabilize the interface between phases A and B and to prevent elements that have migrated to phase B from returning to phase A (the spacing between the pillars 16 being selected to be less than the diameter of the elements E); and
a zone Z4 which permits evacuation of phases A and B via the two independent outlets 11b and 12b permitting separation of phase A depleted of or lacking the elements E and of phase B enriched in the latter.

It should be noted that it would be possible to add a third outlet positioned at the interface of the two phases A and B, which would be intended for collecting a mixture of the latter that is free from the elements E.

It should also be noted that the single row of blocks 14 makes it possible to divert “monodispersed” elements E (i.e. of roughly the same size) without hindering the flow of phase A, and that the spacing between blocks 14 is therefore less than the diameter of the elements E. Thus, a row of blocks 14 acts as a filter, i.e. it blocks, in the direction of flow of phase A, passage of elements whose size exceeds the mesh of the filter, said mesh being defined here by the spacing between two consecutive blocks 14. As for the aforementioned angle of the row of blocks 14, it is a function of the flow velocity and can therefore vary widely from 30 to 85° for example, being reduced for relatively high velocities in order to avoid or minimize impact of elements E on said blocks 14.

It should be noted, moreover, that if the spacing between the pillars 16 providing the nonreturn and interface stabilizing functions is selected to be sufficiently small, then said stabilization can be effected over an appreciable distance relative to the dimensions of unit 10. According to this embodiment, the pillars 16 constitute both an interface stabilizing means and a nonreturn means.

As shown in FIG. 8b, the interface stabilizing means can comprise a surface treatment applied to the inside wall of a microchannel, at the downstream junction Jb. In the example shown in FIG. 8b, the surface treatment is applied on a portion of the separating partition 15 and makes this portion wettable by the liquid phase contacting it. In the example shown, phase A is organic, whereas phase B is aqueous. The interface stabilizing means is then a surface treatment, applied on a face 15a of this partition 15 delimiting (i.e. turned towards) the depleting microchannel 11 (which has diverting blocks 14). This treatment is in this case a treatment for making this portion 15a lipophilic, or hydrophobic, in such a way that this portion 15a is wettable by the organic phase A. Said treatment can for example comprise depositing a lipophilic or hydrophobic material, for example by silanization, on portion 15a.

Alternatively, or simultaneously, a treatment can be applied on face 15b of the separating partition 15 delimiting (i.e. turned towards) the enriching microchannel 12 at junction Jb. This last-mentioned treatment, making the surface of this portion 15b hydrophilic, can comprise fixing a hydrophilic material (e.g. SiO₂, or hydrophilic silane) on said surface.

Thus, a partition 15 made wettable by the liquid phase A or B circulating in the microchannel 11 or 12 delimited by said partition 15, can constitute an interface stabilizing means. Positioned to be adjacent to the particle transfer blocks 14, said partition 15 also forms a nonreturn means with respect to the elements E that are transferred.

As shown in FIG. 9, an extraction unit 110 according to the invention can advantageously use a transverse concentration gradient (see arrow F1) in phase B, the row of blocks 14 then extending transversely from microchannel 11 to microchannel 12 so that the elements E, once transferred to phase B, traverse this concentration gradient. In the case when the gelling effected by this transfer is rapid, this method can limit the swelling of the polymer capsules coating the elements E. As a variant, it is possible to use a double concentration gradient, to carry out sophisticated chemical coating of each capsule.

As shown in FIG. 10, which relates to the case of a population of “polydispersed” elements E (i.e. having various size categories), an extraction unit 210 according to the invention can have at least two oblique rows of blocks 214a and 214b roughly parallel, the row of blocks 214a of larger diameter being placed upstream and extending both in the depleting 211 and enriching 212 microchannels for diverting only the largest elements E to a distal zone (i.e. higher in the figure) of microchannel 212 and then being guided to a distal outlet opposite 212b1 of the latter, whereas the other smaller elements E′ pass through this row 214a and are diverted in their turn by row 214b downstream of the preceding one and only extending across microchannel 211. These elements E′ then rejoin phase B downstream of the elements E, in a proximal zone of microchannel 212 (i.e. lower in the figure) and are channelled to a proximal outlet opposite 212b2 of the latter. The blocks 214a and 214b can also have similar diameters. In this case, the spacing between two consecutive blocks 214a is greater than that between two consecutive blocks 214b.

FIGS. 11 and 12 present, as a guide that is in no way limiting, dimensional values usable for producing an extraction unit 10 such as in FIG. 8.

Firstly, the respective transverse widths W_{ca} and W_{org} of microchannels 11 and 12 near each junction Ja, Jb can be identical or similar, it being specified that these widths can vary from about 1.2 Φ to 10 Φ, where Φ is the average diameter of the elements E to be extracted and that the transverse width of the transfer chamber 13 is for example equal to the sum W_{ca}+W_{org}.

Moreover, the axial distance W_{win} between the inner end of the upstream junction Ja (formed for example by that of the partition 15 prolonging it) and the last of the diverting blocks 14 in the corresponding row (situated roughly opposite said end of junction Ja) can be between about 1.5 Φ and 50 Φ. As for the axial distance Wₛₑₚ between the inner end of the downstream junction Jb (formed for example by that of the partition 15 prolonging it) and this same last block 14, it can be between about 1.5 Φ and 20 Φ.

With regard to each row of blocks 14, 214a, 214b that can be seen in FIGS. 8 to 10, the spacing between blocks can vary from about Φ/5 to Φ/2, and the diameter of each block can be between Φ/10 and Φ/5. The same applies to the spacing between the pillars 16 and their diameter.

In the variant in FIG. 13, the extraction unit 310 differs essentially from that in FIG. 8 in that the means for transferring the elements E, which divert them from phase A to phase B, consist of oblique rows of blocks 314 that are arranged transversely to the microchannels 11 and 12 and are designed for obtaining a deterministic lateral displacement (“DLD”) allowing the elements E to pass, gradually diverting them at each passage from one row to the next row, because the spacing between these blocks is greater than the diameter of the elements E. The blocks 314 are arranged in such a way that the flow lines of the elements E to be diverted gradually move towards the interface between the two phases A and B. Thus, the elements E to be separated follow their flow lines and gradually migrate to the interface. An arrangement of this type does not constitute a filter for the elements to be diverted, but rather a progressive diverting means. According to this variant, two immiscible phases A and B are preferably used. Still according to this variant, interface stabilizing and nonreturn means 16 are arranged downstream of the transfer means 314.

In the variant in FIG. 14, the transfer means diverting the elements E from phase A to phase B within the chamber 413 of the extraction unit 410 consist of a deflector 414a. The elements E are adsorbed on contact with said phase B, if the capillary forces are sufficient. It should be pointed out, however, that the transfer is less effective, as the adsorption of the elements E by phase B to which they are diverted may not take place satisfactorily.

As shown in FIG. 14a, which is a variant of FIG. 14, the deflector 414a can be supplemented with, on the one hand, diverting blocks 14, prolonging it obliquely roughly to the interface between phases A and B and, on the other hand, stabilizing/non-return pillars 16. The diverting blocks 14 are arranged so as to constitute a filter blocking the passage of the elements E to be diverted in the direction of flow of the depleted fluid (fluid flowing in the depleting microchannel). It should be noted that with these pillars 16, more effective transfer is obtained than that provided by unit 410 in FIG. 14, which does not have such pillars 16 and in which the elements adsorbed in phase B can return to phase A.

In the example in FIG. 15, the extraction unit 510 according to the second embodiment of the invention still has its depleting and enriching microchannels 511 and 512, which have their upstream junction Ja and downstream junction Jb in the form of Y-shaped junctions, but the transfer of the elements E from phase A to phase B is effected here without the slightest diverting of these elements E. In fact, an alignment of regularly spaced pillars 514 (for example of square section) preferably on the entire length of the transfer chamber 513 downstream of the upstream junction Ja and which extends as far as the downstream junction Jb in the prolongation of the lateral walls of the inlet 511a of microchannel 511 and of the outlet 512b of microchannel 512 (the inlet 511a and the outlet 512b being envisaged as roughly coaxial), is designed for channelling the elements E almost in a straight line from said inlet 511a of phase A to be depleted to said outlet 512b of phase B to be enriched. This alignment of pillars 514 thus extends parallel to the direction followed by the elements E.

It should be noted that in this second embodiment of the invention, impacts of the elements E on pillars 514 are avoided, which is particularly important for the extraction of fragile elements such as clusters of cells with little cohesion such as the islets of Langerhans.

As can be seen in said FIG. 15, it will also be noted that the interface between phases A and B has a tendency to “rest” on the last pillars 514 situated more downstream of chamber 513, i.e. in the immediate vicinity of junction Jb. In other words, these pillars 514 constitute an interface stabilizing means. And since pillars 514 are also designed for preventing passage of the elements E in outlet 511b of microchannel 511, their alignment on the entire length of chamber 513 along the axis of flow of phase A is preferable with this objective. Thus, the pillars 514 on which the interface between phases A and B is supported also constitute interface stabilizing and nonreturn means.

According to this second embodiment, the row of pillars 514 extends transversely to the direction of flow of phase A. It constitutes a filter for the elements E to be separated, in the sense that it blocks their passage in the direction of flow of phase A in the depleting microchannel 511. It will then be understood that according to this embodiment, this row of pillars 514 constitutes both a transfer means and an interface stabilizing and nonreturn means.

Also preferably, to prevent phase A mixing with phase B, steps are taken to maintain, during extraction, a pressure in the latter that is slightly higher than in phase A, for example by means of coil 20 shown in FIGS. 26 and 27 (or some other means for reducing the head losses, for example by reducing the channel cross-section). This prevents droplets of phase A appearing in phase B, it being specified that, conversely, the formation of droplets of phase B in phase A can be accepted. It should be noted that said means 20 for reducing head losses makes it possible not only to adjust the pressures of phases A and B, but also to maintain their respective velocities fairly close to one another at the transfer chamber, thus avoiding excessive shearing forces on the elements transferred from one phase to another.

As shown in FIG. 16, an extraction unit 610 according to the invention can use more than two different phases Ph1 to Ph3, which circulate in parallel microchannels 611, 612 and 613 defining three inlets 611a to 613a, three outlets 611b to 613b, two upstream junctions Ja and two downstream junctions Jb. The extension of the oblique row of diverting blocks 614, which is formed across the depleting microchannel 611, the intermediate microchannel 612 and ends where 612 meets the enriching microchannel 613 (i.e. at the interface between phases 2 and 3), forces the elements E to pass through phase 2 and then through phase 3. This passage through phase 2 can for example permit chemical or biological modification of the surface of the capsules coating these elements E, before completely gelling said capsules by phase 3. For this unit 610, preferably a phase 1 is used which is immiscible with a phase 2, whereas the phases 2 and 3 can be miscible with one another depending on the application envisaged.

As shown in FIG. 17, when there are two or more than two size categories of the elements E, E′, it is possible to use, in extraction unit 710, several rows of blocks 714a and 714b as in FIG. 10, and three or more than three immiscible liquid phases Ph1 to Ph3. The rows of blocks 714a and 714b constitute filters for elements E and E′ respectively. In fact, they block the passage of these elements E and E′ depending on the direction of flow of their respective microchannels. It can be seen from said FIG. 17 that the smaller elements E′ are located in phase 2 and leave it (via outlet 712b of the intermediate microchannel 712) after crossing the upstream row 714a and being diverted by the downstream row 714b, whereas the larger elements E are diverted by the upstream row 714a to reach phase 3 directly and leave it (via outlet 713b of the enriching microchannel 713). It will be noted, in the embodiments described in FIGS. 16 and 17, that pillars 16 constitute both interface stabilizing means (notably when two phases flowing in two adjacent microchannels are immiscible) and nonreturn means.

FIGS. 18 and 19 illustrate, in relation to the gelling of capsules coating the elements E to be extracted, such as clusters of cells, the two steps of pre-gelling employed respectively in an organic phase (phase A) then gelling by transfer to an aqueous phase (phase B) as presented above, referring to FIGS. 8 to 15.

Pre-gelling can be obtained by contact with:
nanocrystals of polyions permitting gelling of the polymer capsule (which is typically of alginate or similar), where these nanocrystals can be for example of calcium acetate, calcium chloride, barium titanate, calcium phosphate or barium chloride, not necessarily miscible with the organic continuous phase (e.g. based on oil or perfluorinated solvents), or with
nano-emulsions containing polyions permitting gelling.

On contact with these polyions, pre-gelling takes place and the outer envelope of the capsules crosslinks to a very slight thickness, sufficient to stiffen its surface and maintain the spherical shape of the capsule.

Pre-gelling offers numerous advantages, and we may notably mention that it makes it possible to preserve the spherical shape for the capsules, maintain them in physiological conditions, automate encapsulation and gelling, perform multilayer encapsulations and finally remove “satellite” droplets. The latter will in fact be removed downstream of pre-gelling, as they will follow the stream in the depleting channel and pass through the inter-block space 14 acting as filter, owing to the reduced size of these “satellite” droplets.

As can be seen in FIGS. 18 and 19, the pre-gelling module PG is coupled upstream to the extraction unit 10 of FIG. 8, which is advantageously coupled downstream to an optional module for additional encapsulation 30. Once the capsules pre-gelled via module PG are in their carrier fluid (oily phase A), they enter unit 10 and are transferred by the row of blocks 14 to a second immiscible phase B (aqueous). Interface stabilizing means and nonreturn means 16 can also be arranged there. In this example, these means are in the form of pillars 16, providing these two functions simultaneously. When calcium ions (or other polyions permitting gelling) are added to said phase B, complete crosslinking of the alginate coating takes place, and a stable capsule is obtained.

It should be noted, however, that in the case when the immiscible phase B does not contain gelling polyions, it is then possible to form capsules with a liquid core which, although less used at present, offer the advantage of leaving space for the cells that have been encapsulated, and which divide.

It should also be noted that the microfluidic system according to the invention makes it possible to perform gelling at neutral pH and thus maximize the viability of the cells, whereas this is not possible for encapsulations in capsules with a liquid core by the conventional methods in which these capsules are first gelled and then their core is dissolved with agents such as citrate or EDTA.

The additional encapsulation module 30 illustrated in FIGS. 18 and 19 is intended for providing encapsulation of optimum quality, by double coating. This module 30, for example of the “MFFD” type (“Micro Flow Focusing Device”) is coupled to the aqueous phase B containing the capsules for example of alginate in solution. We thus obtain a multilayer capsule C with two coatings C1 and C2 which can be different (alginates of different concentration for example, or else alginate/PLL where PLL is poly-L-lysine), and with improved centering of each element in capsule C (e.g. clusters of cells) as can be seen in FIG. 20, since there is low probability of having two off-centers on one and the same side.

This configuration minimizes the probability of appearance of protrusions during gelling of the capsules, where protrusion denotes a portion of the encapsulated element that is not covered or is very thinly covered with the polymer shell. Production of gelled capsules that do not have any protrusion is particularly important when the encapsulated element is intended to be implanted in a living body, in order to avoid any immune reaction, as such reaction can lead to graft rejection.

As can be seen in FIG. 19, multi-encapsulation can also be performed by increasing the number of encapsulation and gelling steps (application by extraction with two stages 10′, 10″), for example alginate/PLL/alginate encapsulation. Four phases Ph1 to Ph4 are used for this purpose, preferably with:
Ph1: organic phase+calcium nanocrystals,
Ph2: aqueous phase+calcium,
Ph3: aqueous phase+PLL, and
Ph4: aqueous phase+alginate.

In this example, the aqueous phases Ph2 to Ph4 are miscible with one another, whereas the only organic phase Ph1 is not miscible with the other three. Interface stabilizing means consisting of pillars 16 are provided between the transfer blocks 14 and the downstream junction of the microchannels in which phases 1 and 2 circulate, said phases being immiscible.

In the variant in FIG. 19a, multi-encapsulation is performed by arranging several nondiverting extraction units 510′ and 510″ in series, each being of the type as in FIG. 15. As can be seen in this figure, the first extraction unit 510′ is designed, via the pillars 514, for channelling in a straight line the elements E in the form of droplets containing cells carried by phase A to be depleted, to the outlet of phase B to be enriched, which effects gelling of these droplets, and the second extraction unit 510″ is designed, via similar pillars 514, for channelling the droplets gelled in phase B to the outlet of a third phase C containing fresh encapsulating material. These gelled and encapsulated droplets are then in contact with a fourth phase D (new carrier phase) for obtaining double encapsulation of the droplets at the outlet.

The extraction unit 810 in FIG. 21 (a portion of which is shown schematically in FIG. 23) is such that the upstream junction Ja and the downstream junction Jb each have, in top view, a U shape, and unit 810 then has an H shape, the broadened cross-bar of which forms the transfer chamber and the uprights of which form the inlets 811a, 812a and the outlets 811b, 812b. The oblique row of cylindrical diverting blocks 814 (with diameter equal to 40 μm) is combined with an internal deflector 814a of triangular section formed on the outer lateral wall of the depleting microchannel 811 and whose ramp, which makes an angle α for example of 30° with said wall, is prolonged in the same direction by the blocks 814. As a guide, the dimensions h, E and g shown in this example are 800 μm, 80 μm and 40 μm respectively. As for the diamond-shaped pillars 816 intended for interface stabilization and nonreturn of the elements, they have a diagonal of 40 μm. The values given as an example were calculated for a device with a depth of 200 μm.

The variants in FIGS. 22 and 24 illustrate respectively the row of diverting blocks 814 lacking an upstream deflector, and provided with a deflector 814b similar to that in FIGS. 21 and 23 but whose transverse height is much greater, being almost or as large as the width of the depleting microchannel 811.

The extraction unit 910 in FIG. 25 only differs from that in FIG. 21 in that it lacks the alignment of pillars for interface stabilization and nonreturn of the elements. In fact, it can be seen that the transfer means of the latter are exclusively constituted here of an oblique row of cylindrical blocks extending from the outer lateral wall of the depleting microchannel 911 to the downstream junction Jb, so as to divert these elements to the microchannel 912. The angle α, and the distances h and E are for example the same as in FIG. 21.

The microfluidic system illustrated in FIG. 26 and the following figures is suitable for a depth of the microchannels in the substrate 3 of 200 μm. The coil 20, seen in FIGS. 26 and 27, is provided for maintaining, within the extraction unit 1010 (see FIG. 30), a liquid pressure in the enriching phase greater than that in the depleting phase, to prevent droplets of the latter entering said enriching phase. Thus, the hydrodynamic resistances of these phases are adjusted as a function of the viscosity of the latter. As shown in FIG. 27, the characteristics of the enriching microchannel 1012 can be defined in relation to its starting point A′ and arrival point B′ in unit 1010.

The encapsulation unit 40, shown in FIG. 28 (corresponding to the inset “zoom 1” in FIG. 26), is of the “MFFD” type, and its visible dimensions are for example:
a=200 μm b=1.2 mm c=800 μm d=300 μm
e=300 μm f=650 μm α=30°.

As shown in FIG. 29 (corresponding to the inset “zoom 2” in FIG. 26), the characteristics of the depleting microchannel 1011 can be defined in relation to its starting point C′ away from unit 1010 and arrival point D′ at the outlet of the microfluidic system.

As shown in FIG. 30 (corresponding to the inset “zoom 3” in FIG. 26), this H-shaped extraction unit 1010 is similar to that in FIG. 21 (same dimensions h, g, E and α), but omitting the deflector 814a, only having as transfer means the oblique row of cylindrical blocks 1014 and the alignment of stabilizing/non-return pillars 1016.

1. A microfluidic system having a substrate in which a network of microchannels is etched comprising an extraction unit of elements of micrometric or millimetric size and which is covered with a protective cover, said extraction unit comprising:
a depleting microchannel in which a first phase to be depleted circulates,
at least one enriching microchannel in which a second phase to be enriched circulates, said depleting and enriching microchannels meeting in pairs at two junctions, upstream and downstream, forming a transfer chamber between said junctions, each junction being such that the central axes of these microchannels are parallel or form an acute angle on either side of the junction, and
transfer means arranged in said depleting microchannel and configured for transferring said elements from this depleting microchannel to said at least one enriching microchannel,
wherein said transfer means comprise blocks extending transversely to the central axis of said depleting microchannel, and in that the extraction unit further comprises interface stabilizing means which are arranged downstream of the transfer means between said junctions and which comprise pillars or else a surface coating located on an area of the downstream junction facing at least one of the microchannels.

2. The system as claimed in claim 1, wherein said interface stabilizing means are situated near said blocks and are approximately aligned with said downstream junction, said interface stabilizing means moreover performing a nonreturn function of the elements that have been separated from said first phase by said blocks or else being combined with separate means performing said nonreturn function.

3. The system as claimed in claim 1, wherein said interface stabilizing means comprise said pillars that have projecting edges, the last pillar being adjacent to said downstream junction, these pillars preferably being regularly spaced with the first pillar which is adjacent to the last block.

4. The system as claimed in claim 1, wherein said or each upstream junction and said or each downstream junction are prolonged in the direction of the opposite junction by an impermeable separating partition between phases extending over a distance configured to increase the parallelism of the streams of said first and second phases in said chamber.

5. The system as claimed in claim 4, wherein said interface stabilizing means comprise said surface coating which is located on at least one face of said separating partition.

6. The system as claimed in claim 1, wherein said transfer blocks, preferably with a wall without projecting edges such as cylindrical blocks, are arranged in at least one row forming for the or each row an angle from 5° to 85° with the direction of this microchannel and preferably between 20° and 60°, said blocks being configured for selectively diverting some or all of said elements to force them to move towards said or each enriching microchannel.

7. The system as claimed in claim 6, characterized in that said transfer means comprise several said rows of blocks which are arranged successively along said depleting microchannel in said chamber, and which comprise:
an upstream row adjacent to said upstream junction, which moreover extends on at least a portion of the passage cross-section of said adjacent enriching microchannel and which is coupled to a distal outlet of said enriching microchannel, and
at least one downstream row adjacent to said downstream junction, which extends over a passage cross-section less than that of the upstream row and which is coupled to a proximal outlet of said enriching microchannel forming for example a Y-shaped junction with said distal outlet and with the depleting microchannel.

8. The system as claimed in claim 1, wherein said transfer means comprise rows of said blocks which are arranged in said chamber transversely to said depleting microchannel and preferably moreover to the enriching microchannel and which are of the type generating a deterministic lateral displacement (“DLD”) allowing said elements to pass, gradually diverting them at each passage from one row to the next row.

9. The system as claimed in claim 1, wherein said transfer means further comprise at least one deflector which consists of an internal projection of the lateral wall of said depleting microchannel formed opposite said chamber and which has for example a triangular cross-section.

10. The system as claimed in claim 1, wherein said depleting microchannel and enriching microchannel have their upstream and downstream junctions in the form of Y-shaped junctions, said transfer blocks, for example of square section, being situated downstream of said upstream junction and adjacent to said downstream junction, said blocks being regularly spaced in the prolongation of the lateral wall of the inlet of the depleting microchannel which is opposite the inlet of the enriching microchannel, and in the prolongation of the outlet of the enriching microchannel, said outlet being roughly coaxial with the inlet of the depleting microchannel, so as to channel said elements without diverting them from their path from the inlet of said depleting microchannel to the outlet of said enriching microchannel.

11. The system as claimed in claim 1 wherein said extraction unit is coupled downstream to a means for reducing the head losses, such as at least one coil, said means also being included in said network of microchannels and being configured for maintaining a pressure of said second phase greater than that of said first phase to prevent droplets of the latter entering said second phase, said means for reducing the head losses also being configured for obtaining similar velocities for these phases.

12. The system as claimed in claim 1, wherein the system further comprises an encapsulation unit of said elements, to which said extraction unit is coupled upstream, the extraction unit being configured to provide gelling by crosslinking of each polymer capsule obtained at the outlet of the encapsulation unit, a pre-gelling module being optionally interposed between these encapsulation and extraction units, and an additional encapsulation module for example of the microfluidic flow-focusing device (“MFFD”) type optionally being provided downstream of the extraction unit.

13. The use of a microfluidic system as claimed in claim 1 for extracting elements of micrometric or millimetric size from a first liquid phase to be depleted to at least one second liquid phase to be enriched which is or is not miscible with said first phase or with an adjacent intermediate phase.

14. The use of a microfluidic system as claimed in claim 13, wherein the use consists of performing gelling by crosslinking of the polymer coating capsules which are previously formed around said elements within this system and which are for example based on an alginate hydrogel, by transfer of these capsules respectively coating said elements from an oily organic phase to be depleted containing them to an aqueous phase to be enriched which is immiscible with said oily phase and which contains a gelling agent preferably based on polyions, such as calcium ions.

15. The use of a microfluidic system as claimed in claim 13, wherein the use consists in using first and second phases to be depleted and to be enriched that are mutually miscible in pairs and in generating, downstream of said transfer chamber, a transverse concentration gradient.

16. A method of extraction of elements of micrometric or millimetric size from a first liquid phase to be depleted to at least one second liquid phase to be enriched which is or is not miscible with said first phase or with an adjacent intermediate phase, said method comprising contacting the respective streams of these phases, which are compelled to flow by forced convection in laminar conditions in a depleting microchannel and at least one enriching microchannel etched in a substrate of a microfluidic system, in such a way that said streams are, on the one hand, roughly parallel to one another or form an acute angle by meeting at two upstream and downstream junctions between said microchannels and, on the other hand, remaining parallel throughout the duration of their mutual contact, to force the transfer of said elements from one phase to the other exclusively by passive fluidics, characterized in that said method comprises transferring said elements from the depleting microchannel to said at least one enriching microchannel by means of blocks extending transversely to the central axis of said depleting microchannel, then an interface stabilization performed downstream of said blocks and upstream of said downstream junction.

17. The method as claimed in claim 16, wherein said interface stabilization is performed by an arrangement of pillars which are situated near said blocks and which are approximately aligned with said downstream junction, or by a surface treatment located on an area of said downstream junction facing at least one of said microchannels, said surface treatment being for example of the lipophilic or hydrophobic type.

18. The method as claimed in claim 17, wherein the method further comprises performing a nonreturn function of the elements that have been separated from said first phase by said blocks, said nonreturn function resulting from said stabilization or else being performed separately from the latter.
